(19) United States
(12) Patent Application Publication
(10) Pub. No.: US 2010/0053035 A1
(43) Pub. Date: Mar. 4, 2010

(54) ELECTROMAGNETIC WAVE-SHIELDING FILM HAVING NEAR INFRARED SHIELDING FUNCTION AND TRANSPARENCY FUNCTION, OPTICAL FILTER AND PLASMA DISPLAY PANEL COMPRISING THE SAME

(76) Inventors: Su-Rim Lee, Daejeon Metropolitan City (KR); Sang-Hyun Park, Daejeon Metropolitan City (KR); Jung-Doo Kim, Daejeon Metropolitan City (KR); Yeon-Keun Lee, Daejeon Metropolitan City (KR); Hyun-Seok Choi, Daejeon Metropolitan City (KR)

Correspondence Address: MCKENNA LONG & ALDRIDGE LLP, 1900 K STREET, NW, WASHINGTON, DC, 20006, US

(21) Appl. No.: 12/312,068

(22) PCT Filed: Oct. 25, 2007
(86) PCT No.: PCT/KR2007/005293

§ 371 Date: Apr. 24, 2009

(30) Foreign Application Priority Data
Oct. 25, 2006 (KR) 10-2006-0104110

(51) Int. Cl. G09G 3/28; H05K 9/00; G02B 5/22

(52) U.S. Cl. 345/60; 174/389; 361/818; 359/885

(57) ABSTRACT

The present invention provides an electromagnetic wave-shielding film which includes a transparent substrate, an electromagnetic wave-shielding layer which includes a conductive pattern formed in at least a portion of the transparent substrate, and an adhesive transparency layer which is formed on the electromagnetic wave-shielding layer to fill a groove of the conductive pattern and contains a near infrared-absorbing dye, and an optical filter and a plasma display panel including the electromagnetic wave-shielding film.

### TECHNICAL FIELD

The present invention relates to an electromagnetic wave-shielding film which includes an adhesive transparency layer formed on the electromagnetic wave-shielding layer to fill a groove of a conductive pattern of the electromagnetic wave-shielding layer and containing a near infrared-absorbing dye, and an optical filter and a plasma display panel including the electromagnetic wave-shielding film.

### BACKGROUND ART

In general, a display device is the common name of TVs and computer monitors, and includes display modules having display panels used to form images and casings supporting display modules.

A display module includes CRTs (Cathode Ray Tube) for forming images, display panels such as LCDs (Liquid Crystal Display) and plasma display panels (Plasma Display Panel, hereinafter, referred to as “PDP”), and driving circuit substrates for driving display panels. The PDPs may further include optical filters disposed at a front side thereof.

An optical filter is provided at a front side of a PDP, and includes an antireflection film preventing light which is incident from the outside from being reflected, a near infrared absorbing film absorbing near infrared which is generated from display panels to prevent malfunction of electronic apparatuses such as remote controllers, a color compensating film containing a color compensating dye to improve the color purity, and an electromagnetic wave-shielding film shielding an electromagnetic wave which is generated from display panels during operation of display devices.

An electromagnetic wave-shielding film 30 shown in FIG. 1 includes a transparent substrate 31, and an electromagnetic wave-shielding layer which is formed on the transparent substrate 31 and includes a conductive pattern 32 having a groove and a protrusion.

If another functional film, for example, any one of an antireflection film, a near infrared absorbing film, and a color compensating film, is attached to the electromagnetic wave-shielding film having the conductive pattern at an upper part thereof, the electromagnetic wave-shielding film and another functional film are insufficiently attached to each other due to the conductive pattern.

Furthermore, since a fine air layer is formed due to the groove of the electromagnetic wave-shielding film and light is scattered due to the fine air layer, there is a problem in that it is difficult to obtain a clear image.

In order to avoid the above-mentioned problem, it is required that two films are attached to each other by using an adhesive and a transparency process is then performed to remove the fine air layer.

The term “transparency process” means a process for preventing the unclear and frosty image due to the scattering of light, which is caused by the fine air layer, by charging the transparent resin in the fine air layer to make the fine air layer transparent, thereby providing the clear image.

Furthermore, a known optical filter is problematic in that since functional films are separately produced and then integratedly layered by using an adhesive, it is difficult to perform the process, production cost is increased, and it is difficult to produce a thin PDP.

### DISCLOSURE

### Technical Problem

It is an object of the present invention to provide an electromagnetic wave-shielding film having a near infrared absorbing function and a transparency function, and an optical filter and a PDP including the same.

### Technical Solution

The present invention provides an electromagnetic wave-shielding film which includes a transparent substrate, an electromagnetic wave-shielding layer which includes a conductive pattern formed in at least a portion of the transparent substrate, and an adhesive transparency layer which is formed on the electromagnetic wave-shielding layer to fill a groove of the conductive pattern and contains a near infrared-absorbing dye.

The present invention provides an optical filter which includes an electromagnetic wave-shielding film.

The present invention provides a plasma display panel which includes an electromagnetic wave-shielding film.

### ADVANTAGEOUS EFFECTS

According to the present invention, an adhesive transparency layer containing a near infrared-absorbing dye is formed on an upper surface of an electromagnetic wave-shielding film on which a conductive pattern is formed to easily perform a transparency process.

Additionally, since it is unnecessary to form a separate layer having a near infrared absorbing function, a thin optical filter can be produced.

Furthermore, since a production process is simplified due to a significantly simplified structure, productivity can be improved and production cost can be reduced.

### DESCRIPTION OF DRAWINGS

FIG. 1 is a sectional view of a known electromagnetic wave-shielding film;

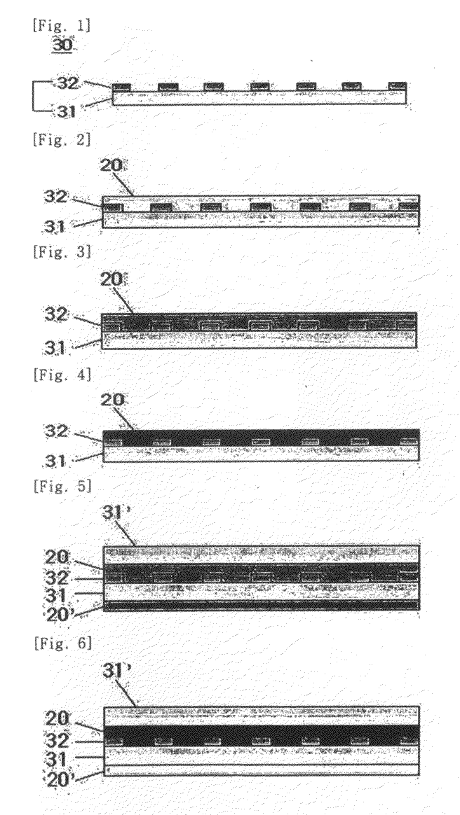

FIGS. 2, 3, and 4 are sectional views of an electromagnetic wave-shielding film according to an embodiment of the present invention;

FIGS. 5 and 6 are sectional views of the electromagnetic wave-shielding film according to the embodiment of the present invention;

FIGS. 7, 8, and 9 are sectional views of an optical filter according to an embodiment of the present invention;

FIGS. 10, 11, and 12 are views illustrating application of the optical filter according to the embodiment of the present invention to PDPs;

FIGS. 13, 14, 15, 16, and 17 are sectional views of an filter wherein transparent glass is layered on the optical filter according to an embodiment of the present invention before the filter is provided in PDPs;

FIGS. 18 and 20 are graphs illustrating measured durability of an electromagnetic wave-shielding film including an adhesive transparency layer containing a near infrared-absorbing dye according to an embodiment of the present invention; and

FIGS. 19 and 21 are graphs illustrating measured durability of an electromagnetic wave-shielding film including an adhesive transparency layer containing a near infrared-absorbing dye and a color compensating dye according to an embodiment of the present invention.

### BEST MODE

An electromagnetic wave-shielding film according to the present invention includes a transparent substrate, an electromagnetic wave-shielding layer which includes a conductive pattern formed in at least a portion of the transparent substrate, and an adhesive transparency layer which is formed on the electromagnetic wave-shielding layer to fill a groove of the conductive pattern and contains a near infrared-absorbing dye.

The transparent substrate may be made of any material as long as the material has excellent light transmittance.

For example, the transparent substrate may be made of one or more selected from the group consisting of polyacryls, polyurethanes, polyesters, polyepoxys, polyolefins, polycarbonates, celluloses, and glass. It is preferable that the transparent substrate be made of transparent PET (polyethylene terephthalate).

The conductive pattern may have a mesh shape including protrusions and grooves.

The conductive pattern may be made of copper, silver, gold, iron, nickel, aluminum, or an alloy thereof. It is preferable that the conductive pattern be made of copper or silver.

The type of adhesive which is used to form the adhesive transparency layer is not limited as long as the adhesive is used to form a typical adhesive sheet or an adhesive film.

Examples of the adhesive which is used to form the adhesive transparency layer may include a pressure sensitive adhesive. Any type of pressure sensitive adhesive may be used as long as the adhesive does not limit transmission of light.

Examples of the adhesive may include an adhesive selected from the group consisting of acryls, urethanes, polyisobutylenes, SBRs (styrene-butadiene rubber), rubbers, polyvinyl ethers, epoxys, melamines, polyesters, phenols, silicons, and a copolymer thereof. It is preferable to use the acryl adhesive.

It is preferable that the acryl adhesive have a glass transition temperature (Tg) of 0° C. or less.

75 to 99.89% by weight of a (meta)acrylic acid ester monomer including an alkyl group having 1 to 12 carbon atoms, 0.1 to 20% by weight of an α, β unsaturated carboxylic acid monomer as a functional monomer, and 0.01 to 5% by weight of a polymeric monomer having a hydroxyl group may be obtained by copolymerizing the acryl adhesive. Since a method of copolymerizing them is well known to those who skilled in the art, a detailed description and condition thereof are omitted.

More preferable examples of the acryl adhesive may include a copolymer of butyl acrylate (BA)/hydroxy ethyl methacrylate (HEMA) and a copolymer of butyl acrylate/acrylic acid (AA).

If the above-mentioned copolymer is used, an excellent absorption function may be ensured at a visible region and a near infrared region of the film in comparison with the other acryl adhesives, and the near infrared-absorbing dye is efficiently stabilized.

The solvent may be further used during the production of the adhesive transparency layer, and a typical organic solvent may be used as the solvent.

Preferably, methyl ethyl ketone (MEK), tetrahydrofurane (THF), ethyl acetate, or toluene may be used. Furthermore, the content of the solvent is not limited.

The adhesive transparency layer may further include a cross-linking agent and a coupling agent.

Examples of the cross-linking agent may include multifunctional compounds such as an isocyanate cross-linking agent, an epoxy cross-linking agent, an aziridine cross-linking agent, and a metal chelate cross-linking agent.

More preferably, the isocyanate cross-linking agent is used and examples of the isocyanate cross-linking agent include, but are not limited to tolylene diisocyanate, xylene diisocyanate, diphenylmethane diisocyanate, and hexamethylene diisocyanate.

The content of the cross-linking agent may be in the range of 0.01 to 2 parts by weight based on 100 parts by weight of the adhesive component.

It is preferable that the coupling agent be a silane coupling agent.

In particular, the silane coupling agent helps to improve adhesion reliability when the silane coupling agent is left over a long period of time under a high temperature and humidity condition.

Examples of the silane coupling agent may include vinyl silane, epoxy silane, or methacryl silane.

Specifically, examples of the silane coupling agent may include vinyltrimethoxy silane, vinyltriethoxy silane, γ-glycidoxypropyltrimethoxy silane, γ-methacryloxypropyltrimethoxy silane, and a mixture thereof.

The content of the silane coupling agent may be in the range of 0.01 to 2 parts by weight based on 100 parts by weight of the adhesive component.

The adhesive transparency layer may further include an additive.

Examples of the additive may include one or more selected from an antioxidant such as phenols and phosphori, a flame retardant such as halogens and phosphoric acids, an ultraviolet-absorbing agent such as silic acids, benzophenones, benzotriazoles, and cyanoacrylates, and an antistatic agent such as alkylene oxides.

The content of the additive may be in the range of 0.01 to 10 parts by weight based on 100 parts by weight of the adhesive component.

Examples of the near infrared-absorbing dye of the adhesive transparency layer may include one or more selected from the group consisting of a metal-complex dye, a phthalocyanine dye, a naphthalocyanine dye, an intermolecular metal-complex type cyanine dye, and a diimmonium dye.

Among them, the metal-complex dye and the phthalocyanine dye are preferably used due to excellent durability in the adhesive and the desirable near infrared absorbing function.

The metal-complex dye may be a compound represented by the following Formula 1 or 2:

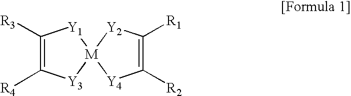

wherein R₁ to R₄ are the same as or different from each other, and are independently a hydrogen atom; a halogen atom; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group,

Y₁ to Y₄ are each independently S or O, and

M is a metal atom selected from the group consisting of Ni, Cu, Pt, and Pd,

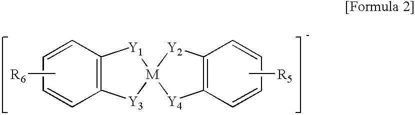

wherein R₅ and R₆ are the same as or different from each other, and are independently a hydrogen atom; a halogen atom; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group,

Y₁ to Y₄ are each independently S or O, and

M is a metal atom selected from the group consisting of Ni, Cu, Pt, and Pd.

The metal-complex dye has desirable durability in the adhesive and a maximized absorbing ability at a near infrared region, and slightly absorbs light at a visible ray region.

The phthalocyanine dye may be a compound represented by the following Formula 3:

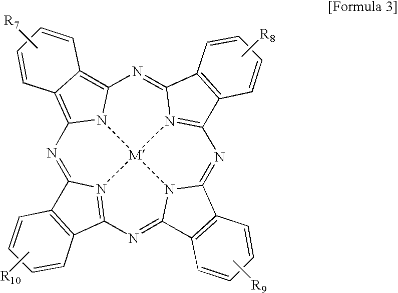

wherein R₇ to R₁₀ are the same as or different from each other, and are independently a hydrogen atom; a halogen atom; a trifluoromethyl group; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group, and

M′ is selected from a divalent metal atom selected from the group consisting of Cu, Zn, Fe, Co, Ni, ruthenium (Ru), rubidium (Rb), palladium (Pd), Pt, Mn, Sn, Mg, and Ti; a 1-substituted trivalent metal atom selected from the group consisting of Al—Cl, Ga—Cl, In—Cl, Fe—Cl, and Ru—Cl; a 2-substituted tetravalent metal atom selected from the group consisting of SiCl₂, GaCl₂, TiCl₂, SnCl₂, Si(OH)₂, Ge(OH)₂, Mn(OH)₂, and Sn(OH)₂; and an oxy metal atom selected from the group consisting of VO, MnO, and TiO.

The naphthalocyanine dye may be a compound represented by the following Formula 4:

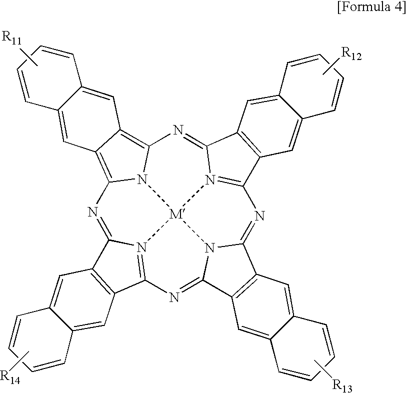

wherein R₁₁ to R₁₄ are the same as or different from each other, and are independently a hydrogen atom; a halogen atom; a trifluoromethyl group; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group, and

M′ is selected from a divalent metal atom selected from the group consisting of Cu, Zn, Fe, Co, Ni, ruthenium (Ru), rubidium (Rb), palladium (Pd), Pt, Mn, Sn, Mg, and Ti; a 1-substituted trivalent metal atom selected from the group consisting of Al—Cl, Ga—Cl, In—Cl, Fe—Cl, and Ru—Cl; a 2-substituted tetravalent metal atom selected from the group consisting of SiCl₂, GaCl₂, TiCl₂, SnCl₂, Si(OH)₂, Ge(OH)₂, Mn(OH)₂, and Sn(OH)₂; and an oxy metal atom selected from the group consisting of VO, MnO, and TiO.

The intermolecular metal-complex type cyanine dye may be a compound represented by the following Formulas 5, 6, or 7:

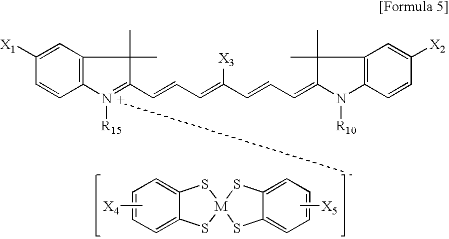

wherein R₁₅ and R₁₆ are the same as or different from each other, and are independently a hydrogen atom; a straight- or branched-chained C_{1˜30} alkyl group which is substituted or unsubstituted with a halogen atom, a cyano group, or a nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group,

X₁ to X₅ are the same as or different from each other, and are independently a halogen group; a nitro group; a carboxyl group; a phenoxycarbonyl group; a carboxylate group; a C_{1˜8} alkyl group which is substituted or unsubstituted with the halogen atom, the cyano group, or the nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group, and

M is a metal atom selected from the group consisting of Ni, Cu, Pt, and Pd,

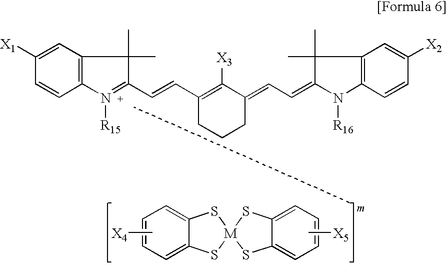

wherein R₁₅, R₁₆, X₁ to X₅, and M are the same as those of Formula 5,

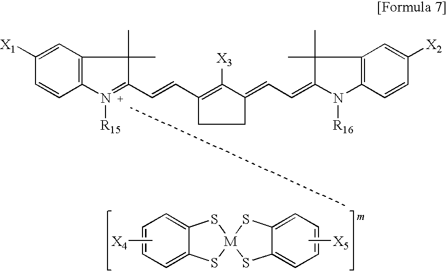

wherein R₁₅, R₁₆, X₁ to X₅, and M are the same as those of Formula 5.

The diimmonium dye may be a compound represented by the following Formula 8:

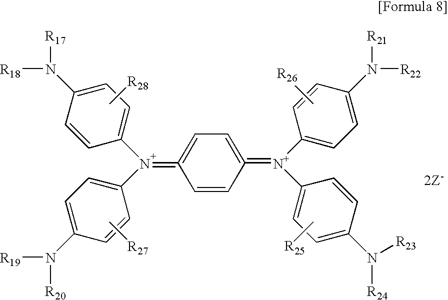

wherein R₁₇ to R₂₄ are the same as or different from each other, and are independently a hydrogen atom; a halogen atom; a trifluoromethyl group; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group,

R₂₅ to R₂₈ are each independently a hydrogen atom; a halogen atom; a cyano group; a nitro group; a carboxyl group; an alkyl group which is substituted or unsubstituted with the halogen atom, the cyano group, or the nitro group; or an alkoxy group which is substituted or unsubstituted with the halogen atom, the cyano group, or the nitro group, and

Z is an organic acid monovalent anion, an organic acid divalent anion, or an inorganic acid monovalent anion.

Examples of the organic acid monovalent anion may include an organic carboxylic acid ion, an organic sulfonic acid ion, and an organic boric acid ion.

Examples of the organic carboxylic acid ion may include acetate ions, lactate ions, trifluoroacetate ions, propionate ions, benzoate ions, oxalate ions, succinate ions, and stearate ions.

Examples of the organic sulfonic acid ion may include methanesulfonate ions, toluenesulfonate ions, naphthalenemonosulfonate ions, chlorobenzenesulfonate ions, nitrobenzenesulfonate ions, dodecylbenzenesulfonate ions, benzenesulfobate ions, ethanesulfonate ions, and trifluoromethanesulfonate ions.

Examples of the organic boric acid ion may include tetraphenylborate ions and butyltriphenylborate ions.

Examples of the organic acid divalent anion may include naphthalene-1,5-disulfonic acid, naphthalene-1,6-disulfonic acid, and naphthalene disulfonic acid derivatives.

Examples of the inorganic acid monovalent anion may include halide ions.

Examples of the halide ions may include fluoride ions, chloride ions, bromide ions, iodide ions, thiocyanate ions, hexafluoroantimononate ions, perchlorate ions, periodate ions, nitrate ions, tetrafluoroborate ions, hexafluorophosphate ions, molybdate ions, tungstate ions, titanate ions, vanadate ions, phosphate ions, and borate ions.

The amount of the added near infrared-absorbing dye may be 0.01 to 10 parts by weight based on 100 parts by weight of the adhesive.

The adhesive transparency layer may further include a neon-cut dye as the color compensating dye.

Examples of the color compensating dye may include one or more selected from the group consisting of a porphyrin dye having a metal-complex in the molecule and an intermolecular metal-complex type cyanine dye.

The porphyrin color compensating dye having the metal-complex in the molecule may be a compound represented by the following Formula 9:

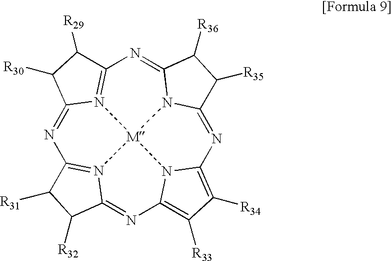

wherein R₂₉ to R₃₆ are the same as or different from each other, and are independently a hydrogen atom; a halogen atom; a C_{1˜16} alkyl group which is substituted or unsubstituted with the halogen atom, the cyano group, or the nitro group; a C_{1˜16} alkoxy group which is substituted or unsubstituted with the halogen atom, the cyano group, or the nitro group; a C_{1˜16} alkoxy group which is substituted or unsubstituted with the halogen atom, the cyano group, or the nitro group and substituted with fluorine; a C_{2˜20} aryl group which is substituted or unsubstituted with the halogen atom, the cyano group, or the nitro group; a C_{2˜20} aryloxy group which is substituted or unsubstituted with the halogen atom, the cyano group, or the nitro group; or a pentagonal cycle which is substituted or unsubstituted with the halogen atom, the cyano group, or the nitro group and has one or more nitrogen atoms, and

M″ is selected from a divalent metal atom selected from the group consisting of a hydrogen atom, an oxygen atom, a halogen atom, Cu, Zn, Fe, Co, Ni, ruthenium (Ru), rubidium (Rb), palladium (Pd), Pt, Mn, Sn, Mg, and Ti; a 1-substituted trivalent metal atom selected from the group consisting of Al—Cl, Ga—Cl, In—Cl, Fe—Cl, and Ru—Cl; a 2-substituted tetravalent metal atom selected from the group consisting of SiCl₂, GaCl₂, TiCl₂, SnCl₂, Si(OH)₂, Ge(OH)₂, Mn(OH)₂, and Sn(OH)₂; and an oxy metal atom selected from the group consisting of VO, MnO, and TiO.

The intermolecular metal-complex type cyanine color compensating dye may be a compound represented by Formula 10 or 11:

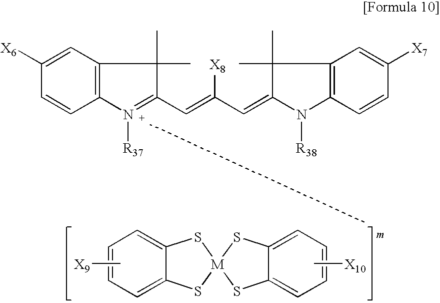

wherein R₃₇ and R₃₈ are the same as or different from each other, and are independently a hydrogen atom; a straight- or branched-chained C_{1˜30} alkyl group which is substituted or unsubstituted with a halogen atom, a cyano group, or a nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group,

X₆ to X₁₀ are the same as or different from each other, and are independently a hydrogen atom; a halogen group; a nitro group; a carboxyl group; a phenoxycarbonyl group; a carboxylate group; a C_{1˜8} alkyl group which is substituted or unsubstituted with the halogen atom, the cyano group, or the nitro group; a C_{1˜8} alkoxy group which is substituted or unsubstituted with the halogen atom, the cyano group, or the nitro group; or a C_{6˜30} aryl group, and

M is a metal atom selected from the group consisting of Ni, Cu, Pt, and Pd,

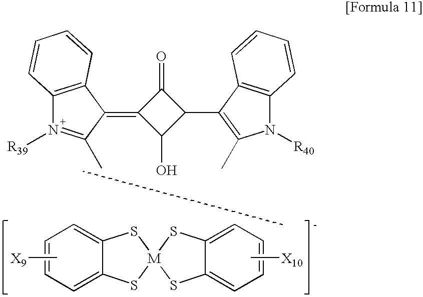

wherein R₃₉ and R₄₀ are the same as or different from each other, and are independently a hydrogen atom; a straight- or branched-chained C_{1˜30} alkyl group which is substituted or unsubstituted with a halogen atom, a cyano group, or a nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group, and

M is a metal atom selected from the group consisting of Ni, Cu, Pt, and Pd.

The amount of the added color compensating dye may be 0.005 to 10 parts by weight based on 100 parts by weight of the adhesive.

The adhesion strength of the adhesive transparency layer is 2 N/25 mm or more at a stripping angle of 180° and a stripping speed of 300 mm/min and preferably 4 N/25 mm or more at the stripping angle of 180° and the stripping speed of 300 mm/min.

If the adhesion strength is less than 2 N/25 mm at the stripping angle of 180° and the stripping speed of 300 mm/min, bubbles may be generated or stripping may occur between the layers, thus reducing durability.

As described above, according to the present invention, in respects to the electromagnetic wave-shielding film having the transparent substrate and the conductive pattern which is formed on the transparent substrate, the adhesive containing the near infrared-absorbing dye is applied on an upper surface of the electromagnetic wave-shielding layer on which the conductive pattern is formed, so that the upper surface of the electromagnetic wave-shielding layer is made flat by filling the groove of the conductive pattern. Next, the transparency process is performed to form the adhesive transparency layer on the upper surface of the electromagnetic wave-shielding layer.

When the adhesive transparency layer is formed, a transparent resin fills the groove, so that an inner portion of the groove becomes transparent. Thus, the unclear and slight frosty image, which is caused by scattering of light due to air remaining in the groove, can be avoided. Accordingly, the clear image can be ensured.

After the adhesive containing the near infrared-absorbing dye is applied, a predetermined pressure may be applied thereto to perform the transparency process. The pressure may be determined by those skilled in the related art according to the type and the amount of adhesive and other process conditions.

The method of producing the adhesive transparency layer having the near infrared absorbing function according to the present invention is not limited thereto.

After the coating solution containing the near infrared-absorbing dye according to the present invention is prepared, the coating solution is applied on at least one side of the flat substrate by using various types of methods and then dried to form the adhesive layer having the near infrared absorbing function. The exposed surface may be covered with a stripping sheet. Alternatively, the solution may be applied on the strip surface of the strip sheet and then dried to form the adhesive layer having the near infrared absorbing function.

Specifically, the added dye and the binder are mixed with each other, the cross-linking agent and the coupling agent are added thereto in a predetermined amount to prepare the coating solution, and the coating solution may be applied on a release film and a transparent substrate and cured to form the adhesive layer.

The thickness of the resulting coating side is more than 5 μm and preferably 10 μm or more. Examples of the coating methods include a spray coating method, a roll coating method, a bar coating method, a spin coating method, a gravure coating method, and a blade coating method.

The produced adhesive transparency layer having the near infrared absorbing function may be attached to the electromagnetic wave-shielding layer having the conductive pattern to produce the desirable electromagnetic wave-shielding film according to the present invention.

Hereinafter, the present invention will be described in detail with reference to the accompanying drawings. The present invention may, however, be embodied in many different forms and should not be construed as being limited thereto.

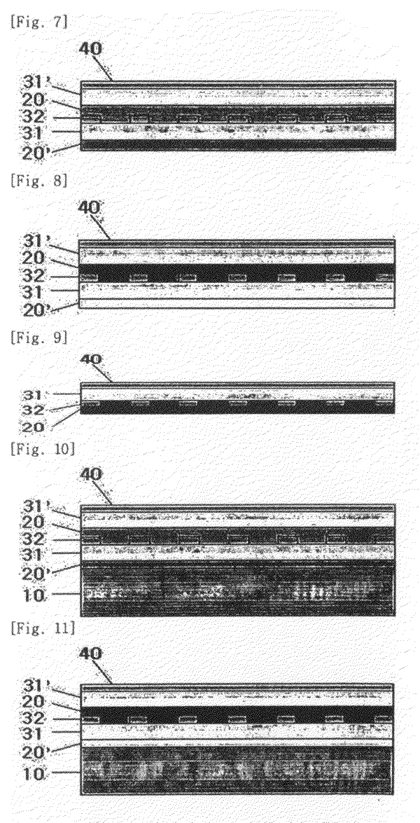

As shown in FIG. 2, the adhesive layer 20 fills the groove of the conductive pattern 32 which is formed on the transparent substrate 31, and the transparency process is performed so that the adhesive layer has the same height as the upper surface of the protrusion of the conductive pattern 32, thus providing the transparency function to the electromagnetic wave-shielding film.

As shown in FIG. 3, during the transparency process according to the present invention, the adhesive containing the near infrared-absorbing dye is applied on the entire upper surface of the electromagnetic wave-shielding film.

In this connection, the adhesive containing the near infrared-absorbing dye fills the groove of the conductive pattern 32 so that the adhesive layer has the same height as the upper surface of the protrusion of the conductive pattern 32.

Therefore, as shown in FIG. 3, the adhesive transparency layer 20 is formed on the electromagnetic wave-shielding layer including the transparent substrate 31 and the conductive pattern 32.

In addition, during the transparency process according to the present invention, as shown in FIG. 4, the adhesive containing the near infrared-absorbing dye and the color compensating dye, particularly the neon-cut dye, is applied on the entire upper surface of the electromagnetic wave-shielding film.

In this connection, the adhesive containing the near infrared-absorbing dye and the color compensating dye fills the groove of the conductive pattern 32, so that the adhesive layer has the same height as the upper surface of the protrusion of the conductive pattern 32.

Therefore, as shown in FIG. 4, an adhesive transparency layer 20 which is made of the adhesive containing the near infrared-absorbing dye and the color compensating dye is formed on the electromagnetic wave-shielding layer including the transparent substrate 31 and the conductive pattern 32.

If the adhesive transparency layer 20 is formed so that the adhesive transparency layer 20 has the same height as the upper surface of the protrusion of the electromagnetic wave-shielding layer, the entire surface of the electromagnetic wave-shielding layer may be etched without a frame to form only the conductive pattern 32. Alternatively, both the conductive pattern 32 and the frame are formed, and in this case, an earth unit may be further provided on the adhesive transparency layer.

The earth unit may be formed by attaching a conductive tape to the circumference of the upper surface of the adhesive transparency layer 20 or by applying a conductive paste on the circumference of the upper surface of the adhesive transparency layer 20.

The conductive tape may be a fabric on which metal such as nickel, copper, aluminum, and gold is applied, and the conductive paste may be obtained by dispersing silver or copper powder in a polymer binder and a solvent.

If the adhesive transparency layer 20 is formed so that the adhesive transparency layer 20 has the same height as the upper surface of the protrusion of the conductive pattern 32, it is preferable that the adhesive transparency layer 20 be formed on the upper surface of the protrusion of the conductive pattern 32 to a thickness in the range of 5 to 30 μm so as to allow a current to desirably flow between the earth and the circumference of the electromagnetic wave-shielding layer.

Conductive particles may be added to the adhesive transparency layer 20 in order to improve flow of the current.

Examples of the conductive particles may include metal powder such as silver or copper, carbon blacks, and carbon nanotubes (CNT).

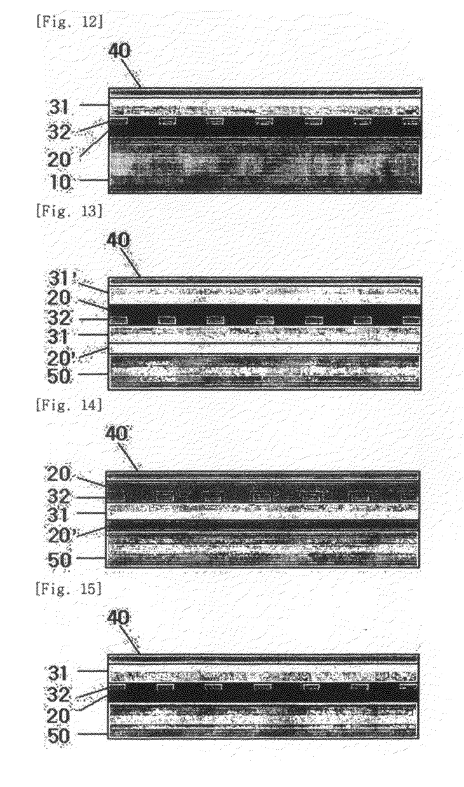

As shown in FIGS. 5 and 6, a release film, a transparent film, or a layer 31′ having other functions may be provided on the adhesive transparency layer 20 of the electromagnetic wave-shielding film which is produced by using the above-mentioned procedure.

Furthermore, the layer having other functions or the adhesive layer 20′ may be added to the lower surface of the transparent substrate 31 of the electromagnetic wave-shielding film. In this case, a release film, a transparent film, or a layer having other functions may be provided on the adhesive layer 20′ which is formed on the lower surface of the transparent substrate 31.

If the adhesive transparency layer 20 of FIG. 5 is a layer which is made of the near infrared absorbing adhesive, the adhesive layer 20′ to be added may be a layer which is made of the adhesive containing the color compensating dye, particularly the neon-cut dye.

If the adhesive transparency layer 20 of FIG. 6 is a layer which is made of the adhesive containing the near infrared-absorbing dye and the color compensating dye, the adhesive layer 20′ may be a layer which is made of a typical adhesive.

Meanwhile, the present invention provides an optical filter which includes the above-mentioned electromagnetic wave-shielding film.

The optical filter of the present invention may further include another functional film which is formed on at least one surface of the upper surface and the lower surface of the above-mentioned electromagnetic wave-shielding film.

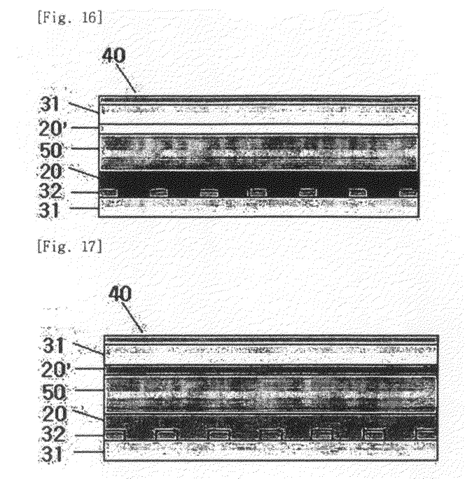

The functional film may be an antireflection film 40 of FIG. 7, a color compensating film for improving a color compensating function of the electromagnetic wave-shielding film, a shock relaxation film, or a contrast ratio improving film.

The functional film may be provided on the upper surface of the adhesive transparency layer 20 of the electromagnetic wave-shielding film according to the present invention or on the lower surface of the adhesive layer 20′ which is formed on the lower surface of the transparent substrate 31.

Examples of the optical filter include the optical filter of FIG. 4. The optical filter may further include an antireflection film 40 which is layered on the upper surface of the electromagnetic wave-shielding film including the adhesive transparency layer 20 having the transparency function and the near infrared absorbing function, and an adhesive layer 20′ which includes the color compensating dye layered on the lower surface of the electromagnetic wave-shielding film.

In addition, the optical filter of FIG. 8 may further include an antireflection film 40 which is layered on the upper surface of the electromagnetic wave-shielding film including the adhesive transparency layer 20 having the transparency function, the near infrared absorbing function, and the color compensating function, and an adhesive layer 20′ which is layered on the lower surface of the electromagnetic wave-shielding film.

Furthermore, the optical filter of FIG. 9 may include the electromagnetic wave-shielding layer having the conductive pattern 32 on the lower surface of the transparent substrate 31 disposed on the lower surface of the antireflection film 40; and the adhesive transparency layer 20 having the transparency function, the near infrared absorbing function, and the color compensating function.

Meanwhile, the present invention provides a PDP which includes the optical filter having the electromagnetic wave shielding film.

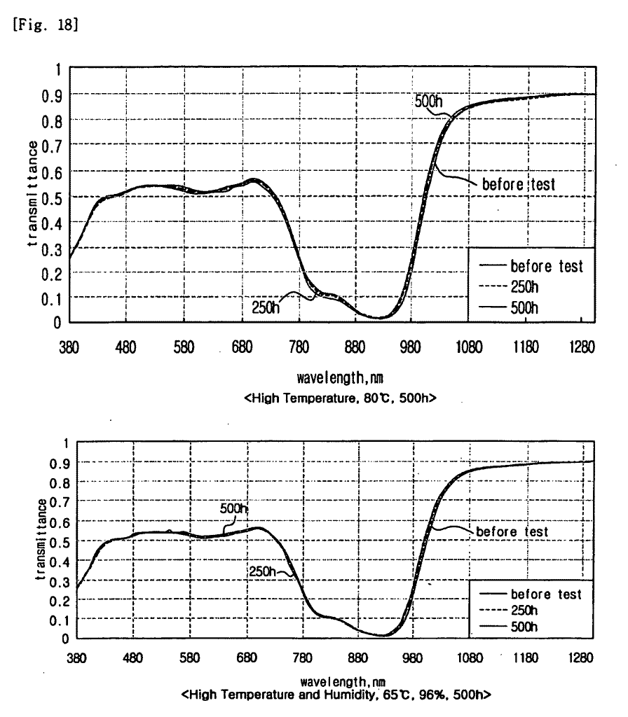

For example, as shown in FIGS. 10 and 11, a PDP 10 may be attached to the lower surface of the adhesive layer 20′ of the optical filter shown in FIGS. 7 and 8.

For example, as shown in FIG. 12, a PDP 10 may be attached to the adhesive transparency layer 20 of the optical filter shown in FIG. 9.

Alternatively, after a transparent glass substrate is attached to the optical filter according to the present invention, the resulting filter may be attached to the PDP so that the transparent glass substrate is interposed between the optical filter and the PDP.

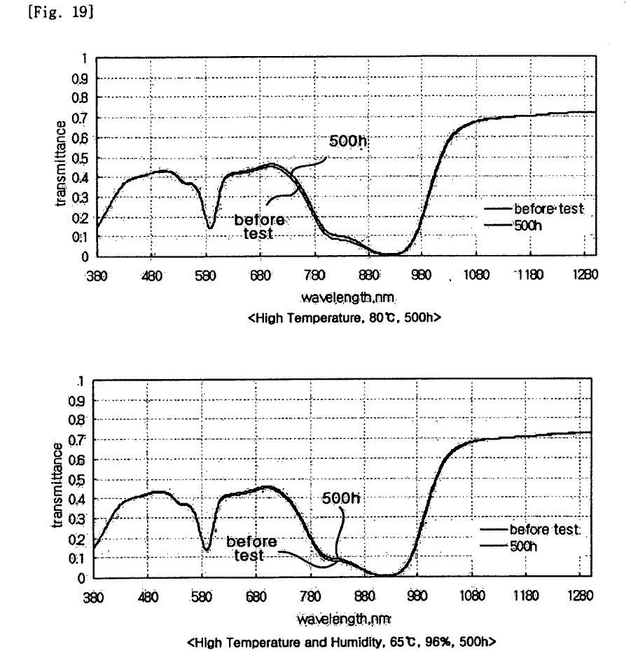

That is, as shown in FIGS. 13 and 14, the transparent glass substrate 50 may be attached to the lower surface of the adhesive layer 20′ of FIGS. 7 and 8 and then attached to the PDP.

Furthermore, as shown in FIG. 15, the transparent glass substrate 50 may be attached to the lower surface of the adhesive transparency layer 20 of the optical filter shown in FIG. 9 and then attached to the PDP.

Furthermore, as shown in FIGS. 16 and 17, the separated functional films may be layered on the upper surface or the lower surface of the transparent glass substrate 50 if necessary.

### MODE FOR INVENTION

A better understanding of the present invention may be obtained in light of the following Examples which are set forth to illustrate, but are not to be construed to limit the present invention.

The electromagnetic wave-shielding film which includes the adhesive transparency layer having the near infrared absorbing function according to the present invention was produced by using the following method, and the test condition of physical properties of the near infrared absorbing adhesive transparency layer was as follows.

<Production of the Film>

1. Production of the coating solution: In Examples, the near infrared-absorbing dye or the near infrared-absorbing dye and the color compensating dye or the neon-cut dye were mixed with each other by using the copolymer of butylacrylate (BA)/hydroxyethylmethacrylate (HEMA) or the copolymer of butylacrylate (BA)/acrylic acid (AA) as the adhesive resin to prepare the coating solution which is used to produce the near infrared absorbing adhesive film.

2. Coating: The coating solution was applied on the release substrate to a thickness of 25 μm and dried at 120° C. for 3 min to laminate the release substrate and the coating layer.

3. Aging: The aging was performed at normal temperature for 7 days.

<Test Condition of Durability>

After the produced adhesive film was applied on the electromagnetic wave-shielding film to perform the transparency process,
High temperature condition: transmittances were compared to each other according to the wavelength before and after the film was left at 80° C. for 500 hours.
High temperature and humidity condition: transmittances were compared to each other according to the wavelength before and after the film was left at a temperature of 65° C. and a humidity (RH) of 96% for 500 hours.

### Example 1

69 g of the copolymer solution containing butylacrylate (BA)/hydroxyethylmethacrylate (HEMA) dissolved in ethylacetate, 0.06 g of metal-complex-based V-63 (Epoline), 0.14 g of phthalocyanine-based 906B (Japanese catalyst), 0.037 g of the isocyanate cross-linking agent, and 0.048 g of the silane coupling agent were added to 31 g of methyl ethyl ketone (MEK) and then mixed with each other to prepare the coating solution.

The coating solution was applied on the release substrate film to a thickness of 25 μm and the release substrate was laminated with another side thereof to produce the near infrared absorbing adhesive film.

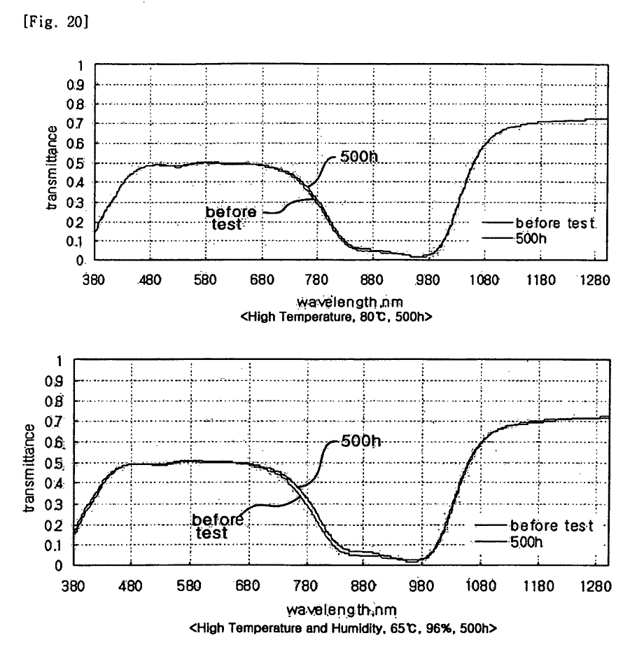

The produced film was applied on the electromagnetic wave-shielding film to perform the transparency process and stored under the condition of the high temperature (80° C.) and the high temperature and humidity (65° C., relative humidity 96%) for 500 hours, and the transmittance was then measured. The results are described in FIG. 18. Evaluation was performed before and after the durability test of the electromagnetic wave-shielding film including the near infrared absorbing adhesive transparency layer according to the present invention. The change in transmittance at a visible ray region after the storage was performed at high temperatures was 0.6%, and the change in near infrared transmittance was 1.6% at 850 nm and 1.3% at 950 nm. The change in transmittance at a visible ray region after the storage was performed at high temperatures and high humidity was 0.6%, and the change in near infrared transmittance was 0.5% at 850 nm and 1.1% at 950 nm.

### Example 2

69 g of the copolymer solution containing butylacrylate (BA)/hydroxyethylmethacrylate (HEMA) dissolved in ethylacetate, 0.06 g of metal-complex-based V-63 (Epoline), 0.14 g of phthalocyanine-based 906B (Japanese catalyst), 0.014 g of porphyrin PD-319 (Mitsui Corp.), 0.037 g of the isocyanate cross-linking agent, and 0.048 g of the silane coupling agent were added to 31 g of methyl ethyl ketone (MEK) and then mixed with each other to prepare the coating solution.

The coating solution was applied on the release substrate film to a thickness of 25 μm and the release substrate was laminated with another side thereof to produce the near infrared absorbing adhesive film.

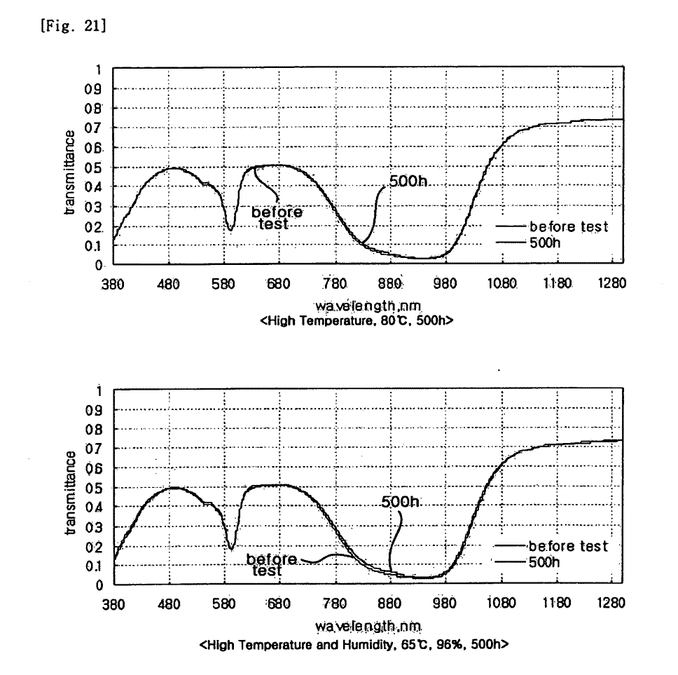

The produced film was applied on the electromagnetic wave-shielding film to perform the transparency process and stored under the condition of the high temperature (80° C.) and the high temperature and humidity (65° C., relative humidity 96%) for 500 hours, and the transmittance was then measured. The results are described in FIG. 19. Evaluation was performed before and after the durability test of the electromagnetic wave-shielding film including the near infrared absorbing and color compensating adhesive transparency layer according to the present invention. The change in transmittance at a visible ray region after the storage was performed at high temperatures was 0.5%, and the change in near infrared transmittance was 1.7% at 850 nm and 0.4% at 950 nm. The change in transmittance at a visible ray region after the storage was performed at high temperatures and high humidity was 0.5%, and the change in near infrared transmittance was 0.9% at 850 nm and 0.4% at 950 nm.

### Example 3

69 g of the copolymer solution containing butylacrylate (BA)/acryl acid (AA) dissolved in ethylacetate, 0.06 g of metal-complex-based EP4445 (Epoline), 0.14 g of phthalocyanine-based 910B (Japanese catalyst), 0.137 g of the isocyanate cross-linking agent, and 0.021 g of the silane coupling agent were added to 31 g of methyl ethyl ketone (MEK) and then mixed with each other to prepare the coating solution.

The coating solution was applied on the release substrate film to a thickness of 25 μm and the release substrate was laminated with another side thereof to produce the near infrared absorbing adhesive film.

The produced film was applied on the electromagnetic wave-shielding film to perform the transparency process and stored under the condition of the high temperature (80° C.) and the high temperature and humidity (65° C., relative humidity 96%) for 500 hours, and the transmittance was then measured. The results are described in FIG. 20. Evaluation was performed before and after the durability test of the electromagnetic wave-shielding film including the near infrared absorbing adhesive transparency layer according to the present invention. The change in transmittance at a visible ray region after the storage was performed at high temperatures was 0.5%, and the change in near infrared transmittance was 0.8% at 850 nm and 0.1% at 950 nm. The change in transmittance at a visible ray region after the storage was performed at high temperatures and high humidity was 1.3%, and the change in near infrared transmittance was 1.9% at 850 nm and 0.3% at 950 nm.

### Example 4

69 g of the copolymer solution containing butyl acrylate (BA)/acryl acid (AA) dissolved in ethylacetate, 0.06 g of metal-complex-based EP4445 (Epoline), 0.14 g of phthalocyanine-based 910B (Japanese catalyst), 0.015 g of porphyrin PD-319 (Mitsui Corp.), 0.137 g of the isocyanate cross-linking agent, and 0.021 g of the silane coupling agent were added to 31 g of methyl ethyl ketone (MEK) and then mixed with each other to prepare the coating solution.

The coating solution was applied on the release substrate film to a thickness of 25 μm and the release substrate was laminated with another side thereof to produce the near infrared absorbing adhesive film.

The produced film was applied on the electromagnetic wave-shielding film to perform the transparency process and stored under the condition of the high temperature (80° C.) and the high temperature and humidity (65° C., relative humidity 96%) for 500 hours, and the transmittance was then measured. The results are described in FIG. 21. Evaluation was performed before and after the durability test of the electromagnetic wave-shielding film including the near infrared absorbing adhesive transparency layer according to the present invention. The change in transmittance at a visible ray region after the storage was performed at high temperatures was 1.1%, and the change in near infrared transmittance was 1.0% at 850 nm and 0.3% at 950 nm. The change in transmittance at a visible ray region after the storage was performed at high temperatures and high humidity was 1.6%, and the change in near infrared transmittance was 1.6% at 850 nm and 0.6% at 950 nm.

1. An electromagnetic wave-shielding film comprising:
a transparent substrate;
an electromagnetic wave-shielding layer which includes a conductive pattern formed in at least a portion of the transparent substrate; and
an adhesive transparency layer which is formed on the electromagnetic wave-shielding layer to fill a groove of the conductive pattern and contains a near infrared-absorbing dye.

2. The electromagnetic wave-shielding film according to claim 1, wherein the conductive pattern has a mesh shape.

3. The electromagnetic wave-shielding film according to claim 1, wherein the conductive pattern is made of copper, silver, gold, iron, nickel, aluminum, or an alloy thereof.

4. The electromagnetic wave-shielding film according to claim 1, wherein the adhesive transparency layer contains an adhesive selected from the group consisting of acryls, urethanes, polyisobutylenes, SBRs (styrene-butadiene rubber), rubbers, polyvinyl ethers, epoxys, melamines, polyesters, phenols, silicons, and a copolymer thereof.

5. The electromagnetic wave-shielding film according to claim 1, wherein the adhesive transparency layer further comprises one or more selected from a cross-linking agent, a coupling agent, an antioxidant, a flame retardant, an ultraviolet-absorbing agent, and an antistatic agent.

6. The electromagnetic wave-shielding film according to claim 1, wherein the near infrared-absorbing dye is one or more selected from the group consisting of a metal complex dye, a phthalocyanine dye, a naphthalocyanine dye, an intermolecular metal-complex type cyanine dye, and a diimmonium dye.

7. The electromagnetic wave-shielding film according to claim 6, wherein the metal-complex dye is a compound represented by Formula 1 or 2: 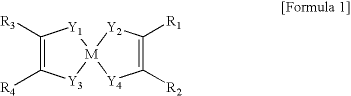
wherein R₁ to R₄ are the same as or different from each other, and are independently a hydrogen atom; a halogen atom; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group,
Y₁ to Y₄ are each independently S or O, and
M is a metal atom selected from the group consisting of Ni, Cu, Pt, and Pd, 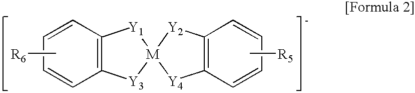
wherein R₅ and R₆ are the same as or different from each other, and are independently a hydrogen atom; a halogen atom; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group,
Y₁ to Y₄ are each independently S or O, and
M is a metal atom selected from the group consisting of Ni, Cu, Pt, and Pd.

8. The electromagnetic wave-shielding film according to claim 6, wherein the phthalocyanine dye is a compound represented by Formula 3: 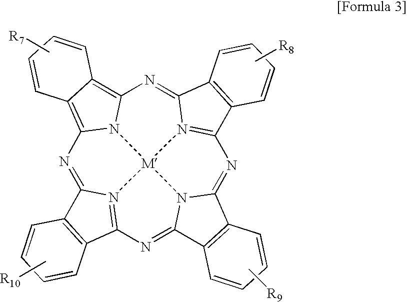
wherein R₇ to R₁₀ are the same as or different from each other, and are independently a hydrogen atom; a halogen atom; a trifluoromethyl group; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜6} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group, and
M′ is selected from a divalent metal atom selected from the group consisting of Cu, Zn, Fe, Co, Ni, ruthenium (Ru), rubidium (Rb), palladium (Pd), Pt, Mn, Sn, Mg, and Ti; a 1-substituted trivalent metal atom selected from the group consisting of Al—Cl, Ga—Cl, In—Cl, Fe—Cl, and Ru—Cl; a 2-substituted tetravalent metal atom selected from the group consisting of SiCl₂, GaCl₂, TiCl₂, SnCl₂, Si(OH)₂, Ge(OH)₂, Mn(OH)₂, and Sn(OH)₂; and an oxy metal atom selected from the group consisting of VO, MnO, and TiO.

9. The electromagnetic wave-shielding film according to claim 6, wherein the naphthalocyanine dye is a compound represented by Formula 4: 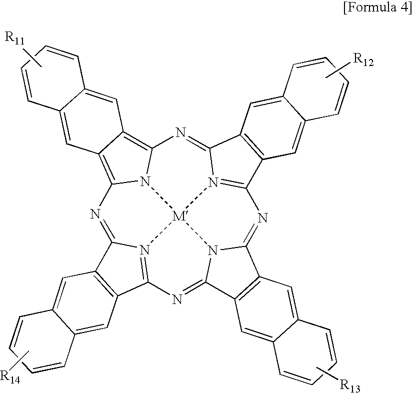
wherein R₁₁ to R₁₄ are the same as or different from each other, and are independently a hydrogen atom; a halogen atom; a trifluoromethyl group; a nitro group; a cyano group; a hydroxy group; a C_{1˜16} alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group, and
M′ is selected from a divalent metal atom selected from the group consisting of Cu, Zn, Fe, Co, Ni, ruthenium (Ru), rubidium (Rb), palladium (Pd), Pt, Mn, Sn, Mg, and Ti; a 1-substituted trivalent metal atom selected from the group consisting of Al—Cl, Ga—Cl, In—Cl, Fe—Cl, and Ru—Cl; a 2-substituted tetravalent metal atom selected from the group consisting of SiCl₂, GaCl₂, TiCl₂, SnCl₂, Si(OH)₂, Ge(OH)₂, Mn(OH)₂, and Sn(OH)₂; and an oxy metal atom selected from the group consisting of VO, MnO, and TiO.

10. The electromagnetic wave-shielding film according to claim 6, wherein the cyanine dye is a compound represented by Formula 5, 6, or 7: 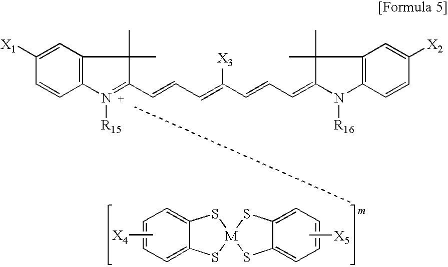
wherein R₁₅ and R₁₆ are the same as or different from each other, and are independently a hydrogen atom; a straight- or branched-chained C_{1˜30} alkyl group which is substituted or unsubstituted with a halogen atom, a cyano group, or a nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group,
X₁ to X₅ are the same as or different from each other, and are independently a halogen group; a nitro group; a carboxyl group; a phenoxycarbonyl group; a carboxylate group; a C_{1˜8} alkyl group which is substituted or unsubstituted with the halogen atom, the cyano group, or the nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group, and
M is a metal atom selected from the group consisting of Ni, Cu, Pt, and Pd, 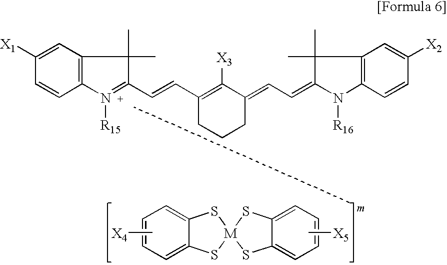
wherein R₁₅ to R₁₆, X₁ to X₅, and M are the same as those of Formula 5, 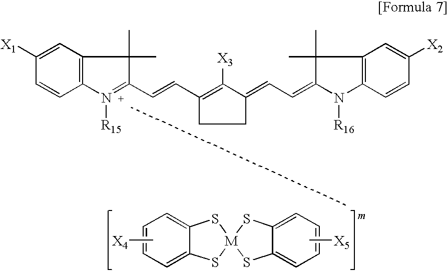
wherein R₁₅ to R₁₆, X₁ to X₅, and M are the same as those of Formula 5.

11. The electromagnetic wave-shielding film according to claim 6, wherein the diimmonium dye is a compound represented by Formula 8: 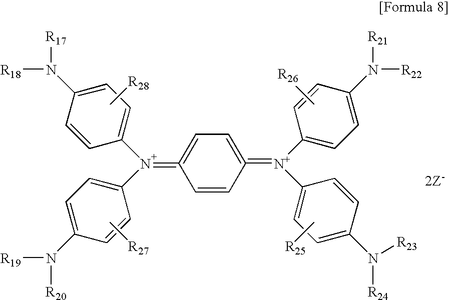
wherein R₁₇ to R₂₄ are the same as or different from each other, and are independently a hydrogen atom; a halogen atom; a trifluoromethyl group; a nitro group; a cyano group; a hydroxy group; a C₁₋₁₆ alkyl group which is substituted or unsubstituted with the halogen atom, the cyano group, or the nitro group; a C_{6˜20} aryl group which is substituted or unsubstituted with the halogen atom, the cyano group, or the nitro group; a C_{1˜16} alkoxy group which is substituted or unsubstituted with the halogen atom, the cyano group, or the nitro group; a C_{6˜20} aryloxy group which is substituted or unsubstituted with the halogen atom, the cyano group, or the nitro group; a C_{1˜16} alkylamino group which is substituted or unsubstituted with the halogen atom, the cyano group, or the nitro group; a C_{6˜20} arylamino group which is substituted or unsubstituted with the halogen atom, the cyano group, or the nitro group; a C_{1˜16} alkylthio group which is substituted or unsubstituted with the halogen atom, the cyano group, or the nitro group; or a C_{6˜20} arylthio group which is substituted or unsubstituted with the halogen atom, the cyano group, or the nitro group,
R₂₅ to R₂₈ are each independently a hydrogen atom; a halogen atom; a cyano group; a nitro group; a carboxyl group; an alkyl group which is substituted or unsubstituted with the halogen atom, the cyano group, or the nitro group; or an alkoxy group which is substituted or unsubstituted with the halogen atom, the cyano group, or the nitro group, and
Z is an organic acid monovalent anion, an organic acid divalent anion, or an inorganic acid monovalent anion.

12. The electromagnetic wave-shielding film according to claim 1, wherein the adhesive transparency layer further comprises a color compensating dye.

13. The electromagnetic wave-shielding film according to claim 12, wherein the color compensating dye is a neon-cut dye.

14. The electromagnetic wave-shielding film according to claim 12, wherein the color compensating dye is one or more selected from the group consisting of an intramolecular metal-complex type porphyrin dye and an intermolecular metal-complex type cyanine dye.

15. The electromagnetic wave-shielding film according to claim 14, wherein the intramolecular metal-complex type porphyrin dye is a compound represented by Formula 9: 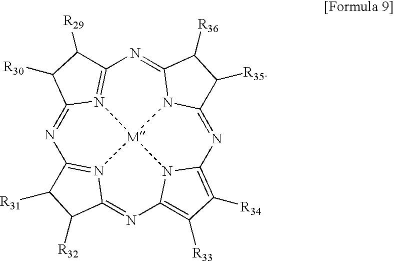
wherein R₂₉ to R₃₆ are the same as or different from each other, and are independently a hydrogen atom; a halogen atom; a C_{1˜16} alkyl group which is substituted or unsubstituted with the halogen atom, the cyano group, or the nitro group; a C_{1˜16} alkoxy group which is substituted or unsubstituted with the halogen atom, the cyano group, or the nitro group; a C_{1˜16} alkoxy group which is substituted or unsubstituted with the halogen atom, the cyano group, or the nitro group and substituted with fluorine; a C_{2˜20} aryl group which is substituted or unsubstituted with the halogen atom, the cyano group, or the nitro group; a C_{2˜20} aryloxy group which is substituted or unsubstituted with the halogen atom, the cyano group, or the nitro group; or a pentagonal cycle which is substituted or unsubstituted with the halogen atom, the cyano group, or the nitro group and has one or more nitrogen atoms, and
M″ is selected from a divalent metal atom selected from the group consisting of a hydrogen atom, an oxygen atom, a halogen atom, Cu, Zn, Fe, Co, Ni, ruthenium (Ru), rubidium (Rb), palladium (Pd), Pt, Mn, Sn, Mg, and Ti; a 1-substituted trivalent metal atom selected from the group consisting of Al—Cl, Ga—Cl, In—Cl, Fe—Cl, and Ru—Cl; a 2-substituted tetravalent metal atom selected from the group consisting of SiCl₂, GaCl₂, TiCl₂, SnCl₂, Si(OH)₂, Ge(OH)₂, Mn(OH)₂, and Sn(OH)₂; and an oxy metal atom selected from the group consisting of VO, MnO, and TiO.

16. The electromagnetic wave-shielding film according to claim 14, wherein the intermolecular metal-complex type cyanine dye is a compound represented by Formula 10 or 11: 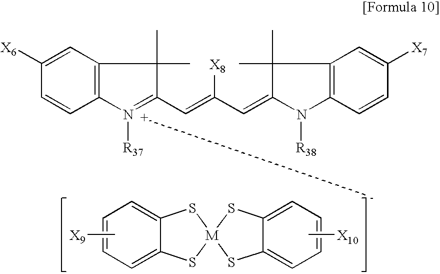
wherein R₃₇ and R₃₈ are the same as or different from each other, and are independently a hydrogen atom; a straight- or branched-chained C_{1˜30} alkyl group which is substituted or unsubstituted with a halogen atom, a cyano group, or a nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group,
X₆ to X₁₀ are the same as or different from each other, and are independently a hydrogen atom; a halogen group; a nitro group; a carboxyl group; a phenoxycarbonyl group; a carboxylate group; a C_{1˜8} alkyl group which is substituted or unsubstituted with the halogen atom, the cyano group, or the nitro group; a C_{1˜8} alkoxy group which is substituted or unsubstituted with the halogen atom, the cyano group, or the nitro group; or a C_{6˜30} aryl group, and
M is a metal atom selected from the group consisting of Ni, Cu, Pt, and Pd, 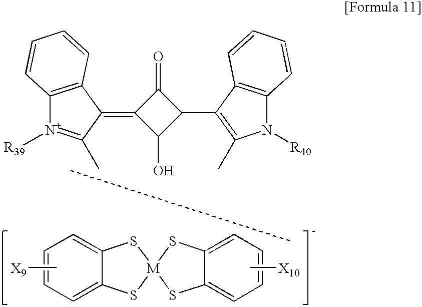
wherein R₃₉ and R₄₀ are the same as or different from each other, and are independently a hydrogen atom; a straight- or branched-chained C_{1˜30} alkyl group which is substituted or unsubstituted with a halogen atom, a cyano group, or a nitro group; a C_{1˜8} alkoxy group which is substituted or unsubstituted with the halogen atom, the cyano group, or the nitro group; or a C_{6˜30} aryl group which is substituted or unsubstituted with the halogen atom, the cyano group, or the nitro group, and
M is a metal atom selected from the group consisting of Ni, Cu, Pt, and Pd.

17. The electromagnetic wave-shielding film according to claim 1, wherein a thickness of the adhesive transparency layer is in the range of 5 to 30 μm based on an uppermost surface of the conductive pattern.

18. The electromagnetic wave-shielding film according to claim 1, wherein an adhesion strength of the adhesive transparency layer is 2 N/25 mm or more at a stripping angle of 180° and a stripping speed of 300 mm/min.

19. The electromagnetic wave-shielding film according to claim 1, further comprising an adhesive layer provided on a lower side of the transparent substrate.

20. An optical filter comprising the electromagnetic wave-shielding film according to claim 1.

21. The optical filter according to claim 20, further comprising a functional film provided on at least one surface of an upper surface and a lower surface of the electromagnetic wave-shielding film.

22. The optical filter according to claim 21, wherein the functional film includes one or more films selected from an antireflection film, a color compensating film, a shock relaxation film, and a contrast ratio improving film.

23. A plasma display panel comprising the electromagnetic wave-shielding film according to claim 1.
